(19) United States
(12) Patent Application Publication
(10) Pub. No.: US 2026/0362596 A1
(43) Pub. Date: Nov. 12, 2026

(54) PRINTED CIRCUIT BOARD AND MANUFACTURING METHOD OF THE SAME

(71) Applicant: Universal Global Technology (Kunshan) Co.,Ltd, KUNSHAN (CN)

(72) Inventors: SHIH-CHANG HUANG, KUNSHAN (CN); CHUN-CHI CHIU, KUNSHAN (CN)

(21) Appl. No.: 19/642,851

(22) Filed: Apr. 9, 2026

(30) Foreign Application Priority Data
May 9, 2025 (CN) 202510595027.8

(51) Int. Cl. H05K 1/11

(52) U.S. Cl. CPC H05K 1/111

(57) ABSTRACT

A printed circuit board and a manufacturing method for the printed circuit board. The printed circuit board includes a substrate, a first circuit metal path, a second circuit metal path, a first barrier structure, and a second barrier structure. The first barrier structure is disposed on the first component placement end of the first circuit metal path to form a first pad region. The second barrier structure is disposed on the second component placement end of the second circuit metal path to form a second pad region. A height value of the first pad region height of the first pad region is same as a height value of the first barrier height of the first barrier structure. A height value of the second pad region height of the second pad region is same as a height value of the second barrier height of the second barrier structure.

### CROSS-REFERENCE TO RELATED PATENT APPLICATION

This application claims the benefit of priority to China Patent Application No. 202510595027.8, filed on May 9, 2025, in the People’s Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### Field of the Disclosure

The present disclosure relates to a printed circuit board and a manufacturing method for the printed circuit board, and more particularly to a printed circuit board and a manufacturing method for the printed circuit board that lower manufacturing costs.

### Background of the Disclosure

Printed circuit boards of existing products having small solder pad components (such as mini LED direct-lit displays or direct-lit backlight products) are generally small in size (for example, less than 225 µm * 225 µm), and all include a solder mask layer. Therefore, during printing, a solder paste thickness and a difference in heights of solder paste between the pads on two sides of a component will increase. This can easily cause component short circuits and component tilting after reflow soldering. Since mini LEDs can have uneven brightness after lighting up when they are disposed on pads having two imbalanced (tilted) sides, a rework is required, thus reducing product yield and increasing costs.

Therefore, how to overcome the above-mentioned problems through improvements in structural design and effectively reduce the probability of component short circuit and tilting after reflow soldering to improve product yield, has become one of the important issues to be addressed in this industry.

### SUMMARY OF THE DISCLOSURE

In order to solve the above-mentioned problems, one of the technical aspects adopted by the present disclosure is to provide a printed circuit board. The printed circuit board includes a substrate, a first circuit metal path, a second circuit metal path, a first barrier structure, and a second barrier structure. The first circuit metal path is disposed on the substrate. The first circuit metal path includes a first component placement end. The second circuit metal path is disposed on the substrate. The second circuit metal path includes a second component placement end. The first component placement end of the first circuit metal path is disposed opposite to the second component placement end of the first circuit metal path. The first barrier structure is disposed on the first component placement end of the first circuit metal path to form a first pad region. The first barrier structure has a first barrier height. The second barrier structure is disposed on the second component placement end of the second circuit metal path to form a second pad region. The second barrier structure has a second barrier height. The first pad region has a first pad region height. A height value of the first pad region height is same as a height value of the first barrier height. The second pad region has a second pad region height. A height value of the second pad region height is same as a height value of the second barrier height.

In order to solve the above-mentioned problems, another one of the technical aspects adopted by the present disclosure is to provide a manufacturing method for a printed circuit board. A first circuit metal path and a second circuit metal path are disposed on a substrate. A metal material layer is disposed on the first circuit metal path, and a metal material layer is disposed on the second circuit metal path. A protective layer is disposed on the metal material layer on the first circuit metal path, and a protective layer is disposed on the metal material layer on the second circuit metal path. A first barrier structure is formed for forming a first pad region on a first component placement end of the first circuit metal path, and a second barrier structure is formed for forming a second pad region on a second component placement end of the second circuit metal path. A first pad material layer is disposed in the first pad region, and a second pad material layer is disposed in the second pad region. The protective layer on the first circuit metal path is removed, and the protective layer on the second circuit metal path is removed.

In order to solve the above-mentioned problems, yet another one of the technical aspects adopted by the present disclosure is to provide a manufacturing method for a printed circuit board. A first circuit metal path and a second circuit metal path are disposed on a substrate. A metal material layer is disposed on the first circuit metal path, and a metal material layer is disposed on the second circuit metal path. By using a laser blocking process, a first barrier structure is formed on a first component placement end of the first circuit metal path to surround a first pad region, and a second barrier structure is formed on a second component placement end of the second circuit metal path to surround a second pad region.

One of the beneficial effects of the present disclosure is that, the printed circuit board and the manufacturing method for the printed circuit board provided by the present disclosure include multiple barrier structures and do not include a solder mask layer. For example, if the solder mask layer is disposed on the circuit board and then the solder paste is printed on the circuit board, the increase of the solder paste volume and the difference of the solder paste thickness on two sides of a component may cause short circuit and tilting of the component after reflow soldering, and such issue can be effectively improved in the present disclosure. Furthermore, the variation in solder paste volume caused by the influence of the solder mask layer thickness when printing the solder paste is eliminated.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a printed circuit board according to a first embodiment of the present disclosure;

FIG. 2 is a cross-sectional view of the printed circuit board of FIG. 1 taken along line II-II;

FIG. 3 is a schematic diagram of the printed circuit board according to a second embodiment of the present disclosure;

FIG. 4 is a cross-sectional view of the printed circuit board of FIG. 3 taken along line IV-IV;

FIG. 5 is a flowchart of a manufacturing method for a printed circuit board according to a third embodiment of the present disclosure;

FIGS. 6A-6F are schematic diagrams of the manufacturing method for the printed circuit board of FIG. 5;

FIG. 7 is a flowchart of the manufacturing method for the printed circuit board according to a fourth embodiment of the present disclosure; and

FIGS. 8A-8C are schematic diagrams of the manufacturing method for the printed circuit board of FIG. 7.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

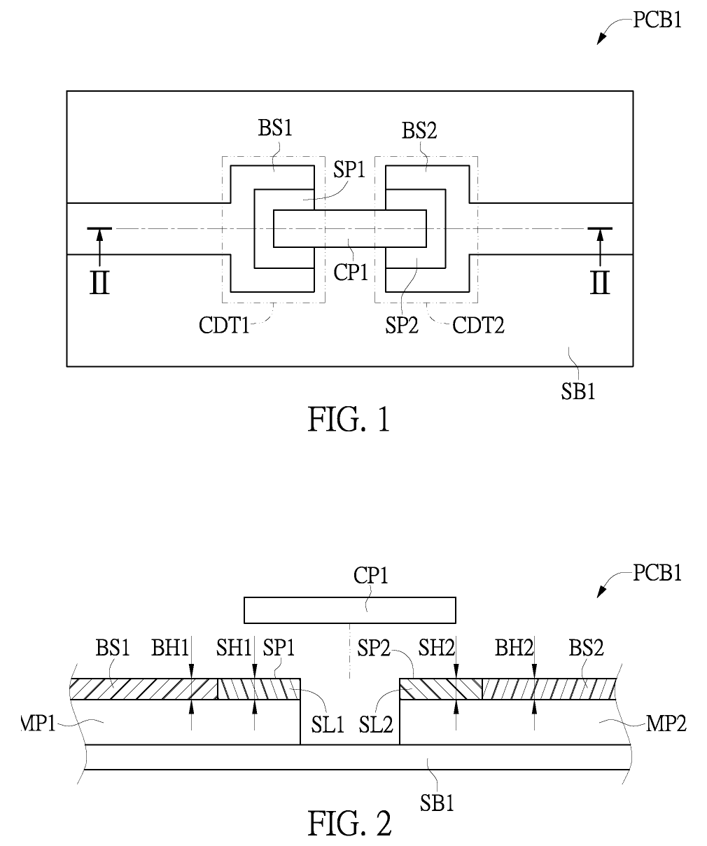

Referring to FIGS. 1 and 2,1 , is a schematic view of a printed circuit board according to a first embodiment of the present disclosure, and FIG. 2 is a cross-sectional view of the printed circuit board of FIG. 1 taken along line II-II.

In this embodiment, a printed circuit board PCB1 is provided. The printed circuit board PCB1 of this embodiment includes multiple barrier structures and does not include a solder mask layer. For example, if the solder mask layer is disposed on the circuit board and then the solder paste is printed on the circuit board, the increase of the solder paste volume and the difference of the solder paste thickness on two sides of a component may cause short circuit and tilting of the component after reflow soldering, and such issue can be effectively improved in the present disclosure. Furthermore, the variation in solder paste volume caused by the influence of the solder mask layer thickness when printing the solder paste is eliminated.

The printed circuit board PCB1 of this embodiment includes a substrate SB1, a first circuit metal path MP1, a second circuit metal path MP2, a first barrier structure BS1, and a second barrier structure BS2. The first circuit metal path MP1 and the second circuit metal path MP2 are both disposed on the substrate SB1.

The first circuit metal path MP1 includes a first component placement end CDT1, and the second circuit metal path MP2 includes a second component placement end CDT2. The first component placement end CDT1 of the first circuit metal path MP1 is disposed opposite to the second component placement end CDT2 of the second circuit metal path MP2.

The first barrier structure BS1 is disposed on the first component placement end CDT1 of the first circuit metal path MP1 to form a first pad region SP1.

The second barrier structure BS2 is disposed on the second component placement end CDT2 of the second circuit metal path MP2 to form a second pad region SP2. The first barrier structure BS1 has a first barrier height BH1, and the second barrier structure BS2 has a second barrier height BH2. The first pad region SP1 has a first pad region height SH1, and a height value of the first pad region height SH1 is same as a height value of the first barrier height BH1. Furthermore, the second pad region SP2 has a second pad region height SH2, and a height value of the second pad region height SH2 is same as a height value of the second barrier height BH2. Moreover, a height value of the first circuit metal path MP1 is configured to be same as a height value of the second circuit metal path MP2. In addition, the height value of the first pad region height SH1 of the first pad region SP1 is also same as the height value of the second pad region height SH2 of the second pad region SP2.

The first barrier structure BS1 is disposed on most of the first circuit metal path MP1 (except the first pad region SP1), and is disposed to surround the first pad region SP1. The second barrier structure BS2 is disposed on most of the second circuit metal path MP2 (except the second pad region SP2), and is disposed to surround the second pad region SP2.

In this embodiment, the first barrier structure BS1 surrounds and is adjacent to the first pad region SP1 on three sides, such that one side of the first pad region SP1 not having the first barrier structure BS1 can face the second pad region SP2 for a component CP1 to be disposed between the first pad region SP1 and the second pad region SP2. Similarly, the second barrier structure BS2 surrounds and is adjacent to the second pad region SP2 on three sides, such that one side of the second pad region SP2 not having the second barrier structure BS2 can face the first pad region SP1, and the component CP1 can be disposed between the first pad region SP1 and the second pad region SP2.

In this embodiment, multiple ones of the first pad region SP1 of the first circuit metal paths MP1 and multiple ones of the second pad region SP2 of the second circuit metal paths MP2 may be disposed on the printed circuit board PCB1. The number of the first pad regions SP1 (including the first barrier structure BS1) and the second pad regions SP2 (including the second barrier structure BS2) that are disposed can be adjusted according to practical requirements and is not limited in the present disclosure. In addition, each of the first barrier structure BS1 and the second barrier structure BS2 is a nickel-containing material layer.

Furthermore, a first pad material layer SL1 is disposed on the first pad region SP1, and a second pad material layer SL2 is disposed on the second pad region SP2. Each of the first pad material layer SL1 and the second pad material layer SL2 is a gold-containing material layer. In addition, as shown in FIGS. 1 and 2 , the component CP1 is such as a mini LED, and can be connected between the first component placement end CDT1 and the second component placement end CDT2, but is not limited thereto.

### Second Embodiment

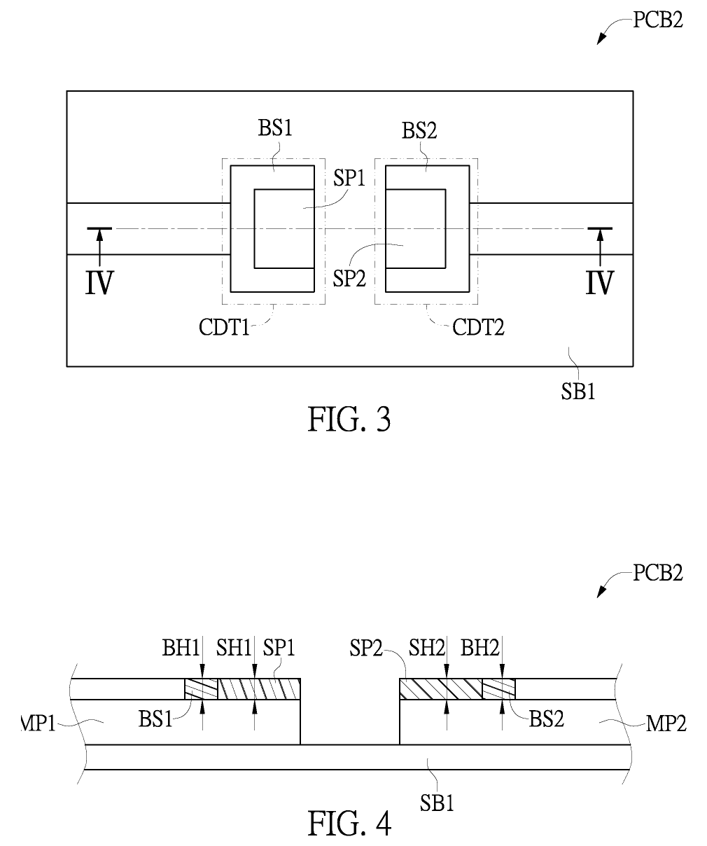

Referring to FIGS. 3 and 4,3 , is a schematic diagram of the printed circuit board according to a second embodiment of the present disclosure, and FIG. 4 is a cross-sectional view of the printed circuit board of FIG. 3 taken along line IV-IV.

A printed circuit board PCB2 in this embodiment is similar to the printed circuit board PCB1 in the first embodiment. A difference between the two circuit boards is that, in this embodiment, the first barrier structure BS1 and the second barrier structure BS2 are formed through a laser blocking process. Specifically, only U-shaped regions of the first barrier structure BS1 and the second barrier structure BS2 undergo the laser blocking process, respectively.

In addition, the first barrier structure BS1 and the second barrier structure BS2 are only disposed at the peripheries of the first pad region SP1 and the second pad region SP2, and the first barrier structure BS1 and the second barrier structure BS2 do not extensively cover the first circuit metal path MP1 and the second circuit metal path MP2, respectively.

Similarly, the first barrier structure BS1 surrounds and is adjacent to the first pad region SP1 on three sides, such that one side of the first pad region SP1 not having the first barrier structure BS1 can face the second pad region SP2, and the component CP1 can be disposed between the first pad region SP1 and the second pad region SP2. The second barrier structure BS2 surrounds and is adjacent to the second pad region SP2 on three sides, such that one side of the second pad region SP2 not having the second barrier structure BS2 can face the first pad region SP1, and the component CP1 can be disposed between the first pad region SP1 and the second pad region SP2.

In this embodiment, the height value of the first circuit metal path MP1 is configured to be the same as the height value of the second circuit metal path MP2. Furthermore, the height value of the first pad region height SH1 of the first pad region SP1 is also the same as the height value of a second pad region height SH2 of the second pad region SP2.

### Third Embodiment

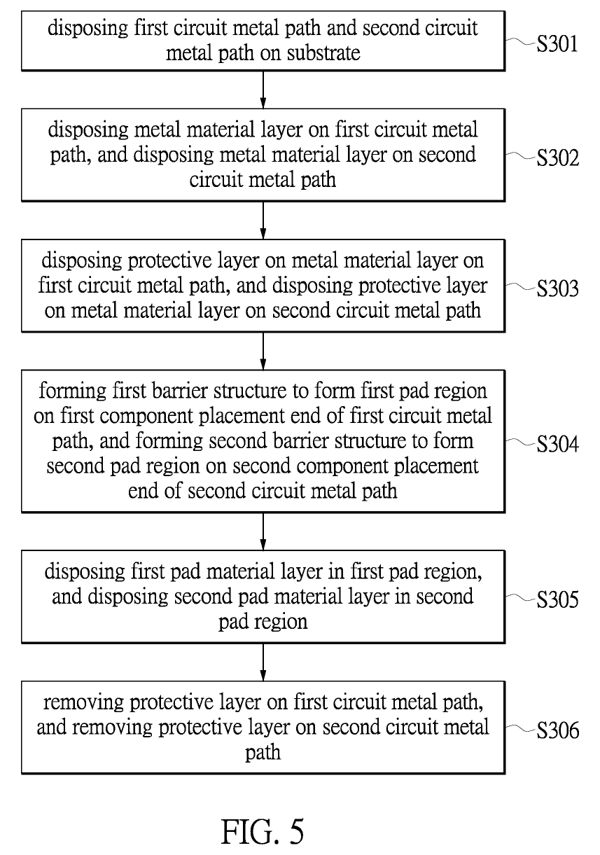

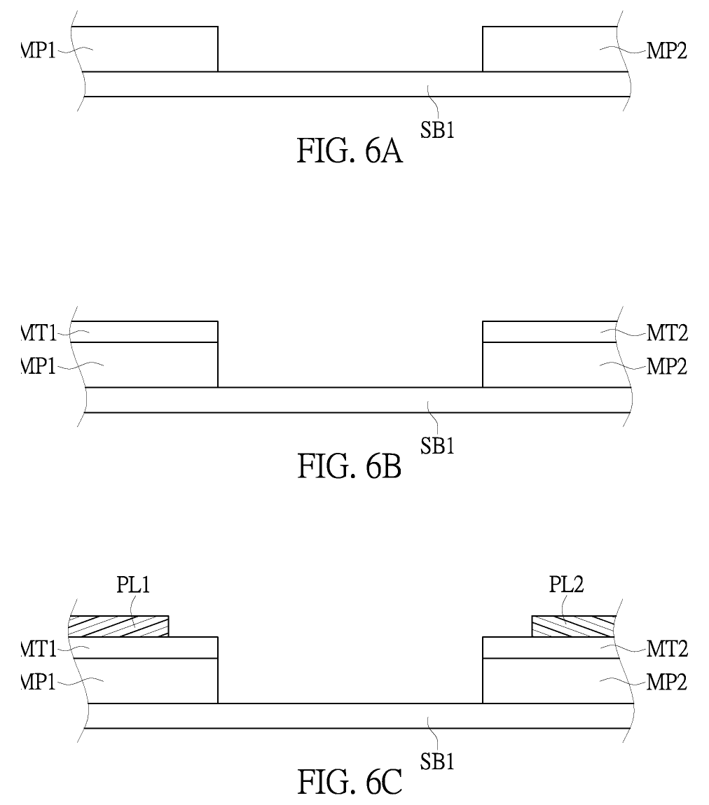

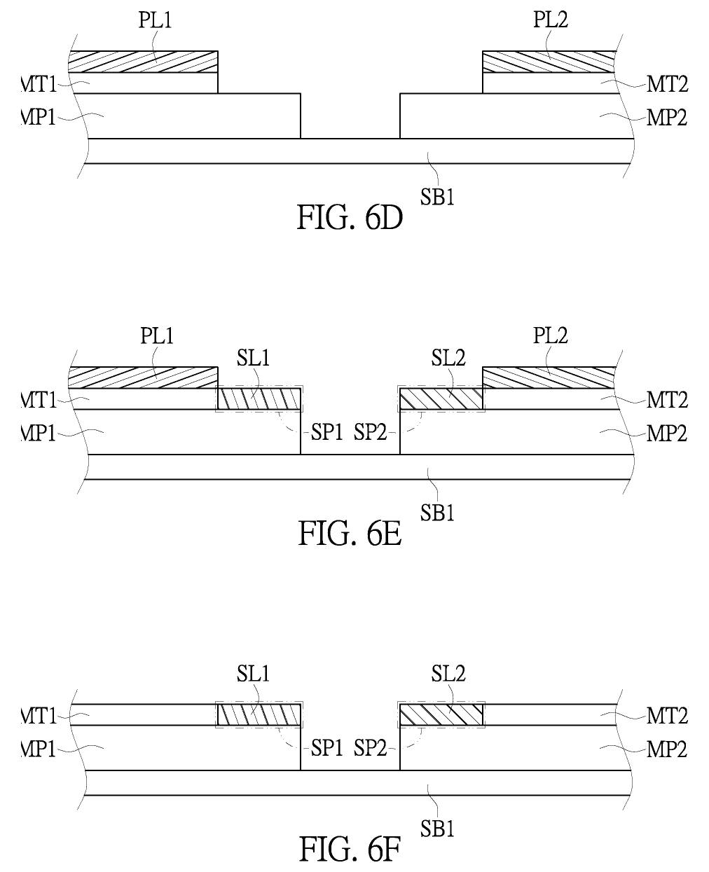

Referring to FIGS. 5 and 6A-6F,5 , is a flowchart of a manufacturing method for a printed circuit board according to a third embodiment of the present disclosure, and FIGS. 6A-6F are schematic diagrams of the manufacturing method for the printed circuit board of FIG. 5.

In this embodiment, a manufacturing method for a printed circuit board is provided, which is suitable for manufacturing the printed circuit board PCB1.

Referring to FIGS. 6A-6F,6A , shows step S301, in which the first circuit metal path MP1 and the second circuit metal path MP2 are disposed on the substrate SB1. The substrate SB1 can be a rigid substrate or a flexible substrate, and is not limited in the present disclosure.

In step S302 and step S303 shown in FIGS. 6B and 6C , the first metal material layer MT1 and the second metal material layer MT2, and the first protective layer PL1 and the second protective layer PL2 are disposed on the first circuit metal path MP1 and the second circuit metal path MP2, respectively.

In step S304 shown in FIG. 6D, a portion of the metal material layer on which the first pad region SP1 and the second pad region SP2 are predetermined to be disposed is removed, so as to form the first barrier structure BS1, the second barrier structure BS2, the first pad region SP1, and the second pad region SP2.

In step S305 shown in FIG. 6E, a first pad material layer SL1 and a second pad material layer SL2 are disposed in the first pad region SP1 and the second pad region SP2, respectively. In this embodiment, each of the first pad material layer SL1 and the second pad material layer SL2 is a gold-containing material layer.

In addition, the height value of the first barrier height BH1 of the first barrier structure BS1 is the same as the height value of the first pad region height SH1 of the first pad region SP1. The height value of the second barrier height BH2 of the second barrier structure BS2 is the same as the height value of the second pad region height SH2 of the second pad region SP2. In addition, in this embodiment, the height value of the first circuit metal path MP1 is configured to be the same as the height value of the second circuit metal path MP2. Furthermore, the height value of the first pad region height SH1 of the first pad region SP1 is the same as the height value of the second pad region height SH2 of the second pad region SP2.

In step S306 shown in FIG. 6F, the first circuit metal path MP1, the first protective layer PL1 on the first barrier structure BS1, the second circuit metal path MP2, and the second protective layer PL2 on the second barrier structure BS2 are removed. Afterwards, a component (not shown in the figures) may be disposed between the first pad region SP1 and the second pad region SP2.

### Fourth Embodiment

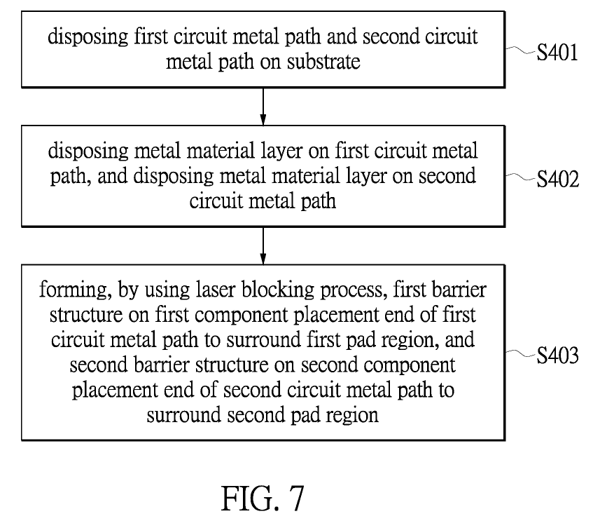

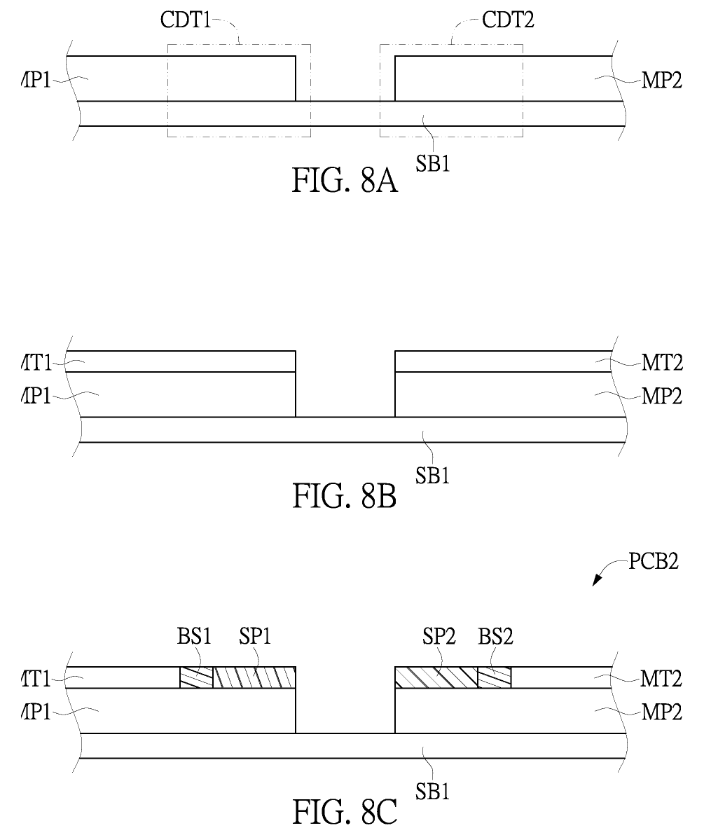

Referring to FIGS. 7,8A,8B, and 8C,7, is a flowchart of the manufacturing method for the printed circuit board according to a fourth embodiment of the present disclosure, and FIGS. 8A-8C are schematic diagrams of the manufacturing method for the printed circuit board of FIG. 7.

In this embodiment, a manufacturing method for a printed circuit board is provided, and the manufacturing method is suitable for manufacturing the printed circuit board PCB2 of the second embodiment.

In step S401 shown in FIG. 8A, firstly, the first circuit metal path MP1 and the second circuit metal path MP2 are disposed on the substrate SB1. The first circuit metal path MP1 and the second circuit metal path MP2 are both disposed on the surface of a same side of the substrate SB1. The substrate SB1 can be a rigid substrate or a flexible substrate, and the present disclosure is not limited thereto.

In step S402 shown in FIG. 8B, the first metal material layer MT1 is disposed on the first circuit metal path MP1, and the second metal material layer MT2 is disposed on the second circuit metal path MP2.

In step S403 shown in FIG. 8C, a laser blocking process is used to form the first barrier structure BS1 at the first component placement end CDT1 of the first circuit metal path MP1 to surround the first pad region SP1, and the second barrier structure BS2 is formed at the second component placement end CDT2 of the second circuit metal path MP2 to surround the second pad region SP2. In this embodiment, each of the first barrier structure BS1 and the second barrier structure BS2 is a U-shaped structure.

The first barrier structure BS1 surrounds and is adjacent to the first pad region SP1 on three sides (including the first circuit metal path MP1 and three sides adjacent to the first pad region SP1), such that one side of the first pad region SP1 not having the first barrier structure BS1 can face the second pad region SP2. Similarly, the second barrier structure BS2 surrounds and is adjacent to the second pad region SP2 on three sides, such that one side of the second pad region SP2 not having the second barrier structure BS2 can face the first pad region SP1.

In this embodiment, metal material layers (the first metal material layer MT1 and the second metal material layer MT2) are respectively a gold-containing material layer or a nickel-containing material layer. Only the first barrier structure BS1 and the second barrier structure BS2 have been processed by the laser blocking process. In addition, in this embodiment, the height value of the first circuit metal path MP1 and the height value of the second circuit metal path MP2 are configured to be the same. Furthermore, the height value of the first pad region height SH1 of the first pad region SP1 and the height value of the second pad region height SH2 of the second pad region SP2 are also the same.

### Beneficial Effects of the Embodiments

In conclusion, one of the beneficial effects of the present disclosure is that, the printed circuit board and the manufacturing method for the printed circuit board provided by the present disclosure include multiple barrier structures and do not include a solder mask layer. For example, if the solder mask layer is disposed on the circuit board and then the solder paste is printed on the circuit board, the increase of the solder paste volume and the difference of the solder paste thickness on two sides of a component may cause short circuit and tilting of the component after reflow soldering, and such issue can be effectively improved in the present disclosure. Furthermore, the variation in solder paste volume caused by the influence of the solder mask layer thickness when printing the solder paste is eliminated.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A printed circuit board, comprising:
a substrate;
a first circuit metal path disposed on the substrate, wherein the first circuit metal path includes a first component placement end;
a second circuit metal path disposed on the substrate, wherein the second circuit metal path includes a second component placement end; and wherein the first component placement end of the first circuit metal path is disposed opposite to the second component placement end of the first circuit metal path;
a first barrier structure disposed on the first component placement end of the first circuit metal path to form a first pad region, wherein the first barrier structure has a first barrier height; and
a second barrier structure disposed on the second component placement end of the second circuit metal path to form a second pad region, wherein the second barrier structure has a second barrier height;
wherein the first pad region has a first pad region height, and a height value of the first pad region is same as a height value of the first barrier height;
wherein the second pad region has a second pad region height, and a height value of the second pad region height is same as a height value of the second barrier height.

2. The printed circuit board according to claim 1, wherein a first pad material layer and a second pad material layer are respectively disposed on the first pad region and the second pad region.

3. The printed circuit board according to claim 1, wherein the first barrier structure is disposed on most of the first circuit metal path except the first pad region to form the first pad region, and the second barrier structure is disposed on most of the second circuit metal path except the second pad region to form the second pad region; and wherein each of the first barrier structure and the second barrier structure is a nickel-containing material layer, a first pad material layer and a second pad material layer are respectively disposed on the first pad region and the second pad region, and each of the first pad material layer and the second pad material layer is a gold-containing material layer.

4. The printed circuit board according to claim 1, wherein the first barrier structure is partially disposed on the first circuit metal path and surrounds the first pad region, and the second barrier structure is partially disposed on the second circuit metal path and surrounds the second pad region.

5. The printed circuit board according to claim 4, wherein each of the first barrier structure and the second barrier structure is a gold-containing material layer or a nickel-containing material layer.

6. The printed circuit board according to claim 5, wherein the first barrier structure and the second barrier structure are formed through a laser blocking process.

7. A manufacturing method for a printed circuit board, comprising:
disposing a first circuit metal path and a second circuit metal path on a substrate;
disposing a metal material layer on the first circuit metal path, and disposing a metal material layer on the second circuit metal path;
disposing a protective layer on the metal material layer on the first circuit metal path, and disposing a protective layer on the metal material layer on the second circuit metal path;
forming a first barrier structure to form a first pad region on a first component placement end of the first circuit metal path, and forming a second barrier structure to form a second pad region on a second component placement end of the second circuit metal path;
disposing a first pad material layer in the first pad region, and disposing a second pad material layer in the second pad region; and
removing the protective layer on the first circuit metal path, and removing the protective layer on the second circuit metal path.

8. The manufacturing method according to claim 7, wherein a height value of a first barrier height of the first barrier structure is same as a height value of a first pad region height of the first pad region, a height value of a second barrier height of the second barrier structure is same as a height value of a second pad region height of the second pad region, and each of the metal material layer, the first barrier structure, and the second barrier structure is a nickel-containing material layer.

9. A manufacturing method for a printed circuit board, comprising:
disposing a first circuit metal path and a second circuit metal path on a substrate;
disposing a metal material layer on the first circuit metal path, and disposing a metal material layer on the second circuit metal path; and
forming, by using a laser blocking process, a first barrier structure on a first component placement end of the first circuit metal path to surround a first pad region, and a second barrier structure on a second component placement end of the second circuit metal path to surround a second pad region.

10. The manufacturing method according to claim 9, wherein the metal material layer is a gold-containing material layer or a nickel-containing material layer.
